(19) United States
(12) Patent Application Publication
(10) Pub. No.: US 2026/0305438 A1
(43) Pub. Date: Oct. 1, 2026

(54) THERMOCOMPRESSION BONDING METHODS AND BUFFER LAYERS THEREFOR

(71) Applicant: Purdue Research Foundation, West Lafayette, IN (US)

(72) Inventors: Carol Handwerker, Washington, DC (US); Debargha Paul, West Lafayette, IN (US); Ke Xu, West Lafayette, IN (US); Xinghang Zhang, West Lafayette, IN (US)

(21) Appl. No.: 19/097,377

(22) Filed: Apr. 1, 2025

(51) Int. Cl. H01L 23/00

(52) U.S. Cl. CPC H10W 72/072; H10W 72/20; H10W 72/90; H10W 72/07232; H10W 72/252; H10W 72/923; H10W 72/952

(57) ABSTRACT

Processes for bonding substrates together. Such a process includes mating a copper film on a first substrate with copper pillars on a second substrate so that a surface of the copper film contacts surfaces of the copper pillars and so that a buffer layer is between the surface of the copper film and the surfaces of the copper pillars. The buffer layer is cobalt or nickel. The copper film is thermocompression bonded to the copper pillars at a bonding temperature while the first and second substrates are subjected to compression that presses the copper film and the copper pillars together at a bonding pressure.

### BACKGROUND OF THE INVENTION

The present invention generally relates to metal-metal bonding methods and systems. The invention particularly relates to methods and systems for thermocompression bonding of copper materials, a particular example being wafer-to-wafer bonding employed in integrated circuits.

Emerging integrated circuits require high-density interconnect layers with minimum delay and lower power dissipation. Metal-metal bonding has emerged as a desirable method for stacking wafers containing integrated circuits due to less consumption of device area and higher signal bandwidth. Copper-copper bonding is currently preferred for metal-metal bonding in integrated circuits due to the ability of copper to exhibit good electrical and mechanical properties along with the compatibility of copper with semiconductor devices.

Thermocompression bonding is a type of solid-to-solid bonding that is widely used in packaging of integrated circuits in the semiconductor industry. Thermocompression bonding involves the application of both heat and pressure at the surfaces to be bonded. Metal-metal bonding at room temperature requires relatively higher pressure levels to eliminate roughness from the surfaces being bonded. Current practices using thermocompression bonding typically involve compromises in pressure and temperature to obtain an ideal bond. The application of heat reduces the level of pressure required by softening to some extent the material(s) being bonded together. High temperatures and pressures can limit the suitability of thermocompression bonding due to adverse effects on performance and integrity of integrated circuit devices being joined. Thus, it is desirable to utilize a combination of minimum pressure and temperature when bonding circuit devices.

A challenge when bonding two surfaces occurs when the surfaces have dissimilar surface roughnesses. Bonding of two surfaces with similar roughnesses can be achieved peak to peak or peak to valley alignment of surface features, as compared to bonding of two surfaces with different roughnesess. Voids are often present at the bond interface between surfaces with dissimilar roughnesses due to mismatches that can be difficult to eliminate even through careful selection of temperatures and pressures.

The tendency for copper surfaces to rapidly form an oxide layer is another significant barrier to obtaining a good quality bond to a copper surface. Exposed copper is prone to oxide formation as oxygen atoms diffuse easily into copper, resulting in a clear trace of oxygen atoms near the intended bond interface that inhibits bonding and the diffusion of metal atoms necessary to obtain a good bond.

In view of the above, there is an ongoing desire to consistently obtain quality bonds via thermocompression bonding.

### BRIEF SUMMARY OF THE INVENTION

The intent of this section of the specification is to briefly indicate the nature and substance of the invention, as opposed to an exhaustive statement of all subject matter and aspects of the invention. Therefore, while this section identifies subject matter recited in the claims, additional subject matter and aspects relating to the invention are set forth in other sections of the specification, particularly the detailed description, as well as any drawings.

The present invention provides, but is not limited to, methods and systems for thermos-compression bonding of copper materials.

According to one nonlimiting aspect, a process is provided that includes mating a copper film on a first substrate with copper pillars on a second substrate so that a surface of the copper film contacts surfaces of the copper pillars and so that a buffer layer is between the surface of the copper film and the surfaces of the copper pillars. The buffer layer is cobalt or nickel. The copper film is thermocompression bonded to the copper pillars at a bonding temperature while the first and second substrates are subjected to compression that presses the copper film and the copper pillars together at a bonding pressure.

Technical aspects of systems and methods as described above preferably include the ability of a buffer layer to promote thermocompression bonding to a copper surface, and particularly between two copper surfaces, such as but not limited to a copper film and a copper pillar. A buffer layer as described above is preferably capable of inhibiting oxidation of copper surfaces and promote diffusion of copper atoms, and in so doing can promote improved bonding characteristics at relatively low bonding temperatures and pressures, for example, temperatures of about 400° C. down to about 50° C. and pressures of about 100 MPa down to about 0.1 MPa.

These and other aspects, arrangements, features, and/or technical effects will become apparent upon detailed inspection of the figures and the following description.

### BRIEF DESCRIPTION OF THE DRAWINGS

FIG. 1 schematically represents a nonlimiting example of a thermocompression bonding process performed between copper features on two substrates utilizing a buffer layer in accordance with certain aspects of the invention. The lefthand image of FIG. 1 represents the lower substrate as equipped with multiple nanotwinned (NT) copper (Cu) pillars and represents the upper substrate as equipped with an NT copper film overlaid by a buffer layer. The righthand image in FIG. 1 schematically represents the result of bonding the copper film of the upper substrate to the copper pillars of the lower substrate after the application of pressure while the substrates are at an elevated temperature.

FIG. 2A is a scanning electron microscope (SEM) image showing the morphology of NT copper pillars on an Si (110) substrate, and FIG. 2B shows a magnified image of an NT copper pillar of FIG. 2A.

FIG. 3A is an SEM image of a bond interface between an NT copper pillar and an NT copper film that were thermocompression bonded together with the use of a silver (Ag) buffer layer, and FIG. 3B is a magnified view of a region of the bond interface within the box of FIG. 3A and reveals a gap at the bond interface that was sufficient to inhibit complete bonding of the pillar and film.

FIG. 4A is an SEM image of a bond interface between an NT copper pillar and an NT copper film that were thermocompression bonded together with the use of a copper (Cu) buffer layer, and FIG. 4B is a magnified view of a region of the bond interface within the box of FIG. 4A and reveals a gap at the bond interface that was sufficient to inhibit complete bonding of the pillar and film.

FIG. 5A is an SEM image of a bond interface between an NT copper pillar and an NT copper film that were thermocompression bonded together with the use of a cobalt (Co) buffer layer, and FIG. 5B is a magnified view of a region of the bond interface within the box of FIG. 5A and reveals a successful bond at the bond interface between the pillar and film exemplified by no visible gaps or voids within the interface.

FIG. 6A is an SEM image of a bond interface between an NT copper pillar and an NT copper film that were thermocompression bonded together with the use of a nickel (Ni) buffer layer, and FIG. 6B is a magnified view of a region of the bond interface within the box of FIG. 6A and reveals a successful bond at the bond interface between the pillar and film exemplified by no visible gaps or voids within the interface.

FIGS. 7A and 7B are bright-field transmission electron microscope (BFTEM) images of a bond interface between an NT copper pillar and an NT copper film that were thermocompression bonded together with the use of a nickel (Ni) buffer layer and reveal successful bonds at the bond interfaces between the pillars and films without the presence of significant residual voids.

FIG. 8A is a high angle annular dark-field (HAADF) image of a bond interface between an NT copper pillar and an NT copper film that were thermocompression bonded together with the use of a nickel (Ni) buffer layer interface. FIG. 8B is an HAADF image of the bond interface superimposed with a compositional analysis of the bond interface.

FIG. 9 is a graph containing a line scan profile along a line indicated by an arow in FIG. 8B and labeled (c) showing an increase in nickel concentration near the bond interface and a gradual decrease in oxygen concentration.

### DETAILED DESCRIPTION OF THE INVENTION

The intended purpose of the following detailed description of the invention and the phraseology and terminology employed therein is to describe what is shown in the drawings, which include the depiction of and/or relate to one or more nonlimiting embodiments of the invention, and to describe certain but not all aspects of what is depicted in the drawings, including the embodiment(s) to which the drawings relate. The following detailed description also identifies certain but not all alternatives of the embodiment(s) depicted in the drawings. As nonlimiting examples, the invention encompasses additional or alternative embodiments in which one or more features or aspects shown and/or described as part of a particular depicted embodiment could be eliminated, and also encompasses additional or alternative embodiments that combine two or more features or aspects described as part of different embodiments. Therefore, the appended claims, and not the detailed description, are intended to recite what are believed to be aspects of the invention, including certain but not necessarily all of the aspects and alternatives described in the detailed description.

The following disclosure describes methods and systems by which buffer layers formed of certain materials were shown to promote thermocompression bonding between copper surfaces. Investigations were conducted to explore thermocompression bonding between nanotwinned copper films and nanotwinned copper pillars. Whereas buffer layers of certain materials were shown to successfully promote improved bonding characteristics, buffer layers formed of certain other materials did not and resulted in incomplete or no bonding.

Candidate materials for buffer layers were investigated on the basis of their ability to inhibit oxidation of the copper surfaces by reducing the oxygen concentration at the thermocompression bond interface and their ability to enhance the bonding process by promoting the diffusion of copper atoms into and through the bond interface. Because high temperatures and pressures can limit the applications in which thermocompression bonding can be used due to adverse effects on the performance of a system, the thermocompression bonding processes were conducted at relatively low temperatures and pressures, generally using bonding temperatures in a range of 275 to 300° C. and a bonding pressure of 1 MPa.

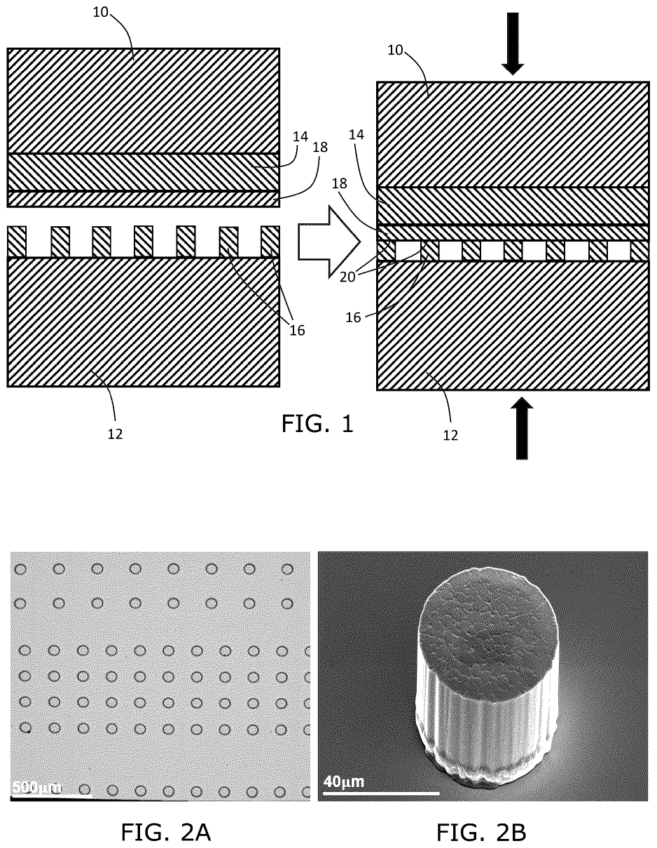

A representation of a thermocompression bonding process and arrangement used in the investigations is schematical depicted in FIG. 1, which depicts a pair of substrates 10 and 12 aligned with each other for thermocompression bonding (lefthand side of FIG. 1) and the result of thermocompression bonding the substrates 10 and 12 together (righthand side of FIG. 1). Si (110) substrates were utilized in the investigations. For the investigations, nanotwinned (NT) copper films 14 and pillars 16 with (111) texture and high-density nanotwins were prepared via an electrodeposition method. The NT copper pillars 16 (FIGS. 2A and 2B) were developed on one of each pair of substrates (the bottom substrate 12 in FIG. 1) to have heights of about 20 μm and diameters of about 50 μm. An NT copper film 14 was grown on the other substrate (the top substrate 10 in FIG. 1) of each pair to have a thickness of about 10 μm thickness. The process of thermocompression bonding the substrates 10 and 12 together was with the intent of creating bond interfaces 20 between the copper film 14 of the substrate 10 and each individual pillars 16 of the substrate 12. The arrows within the righthand side of FIG. 1 represent the substrates 10 and 12 being subjected to compression utilizing a predetermined pressure that presses the copper film 14 and the copper pillars 16 together.

For the investigations, buffer layers 18 were deposited on the surfaces of the copper films 14 using DC magnetron sputtering at room temperature. A variety of materials for the buffer layer 18 were explored, including titanium, silver, cobalt, nickel, and copper, to analyze the bonding process. Prior to depositing the buffer layers 18, the copper films 14 were cleaned with 13% HF acid for 1 minute, after which the substrates 10 bearing the copper films 14 were transferred to a sputtering chamber for deposition of the buffer layers 18. During deposition, the base pressure was maintained to about 5.0 ×10⁻⁸ torr while argon gas flow was maintained at about 3.5 torr.

Following deposition, the substrates 10 and 12 were cleaned by dipping in 13% HF acid for one minute and then ultrasonic cleaning in reverse osmosis (RO) water for ten minutes. After cleaning, the substrates 10 and 12 for each test specimen were aligned with each other and the film 14 and pillars 16 of the substrates 10 and 12 were brought into contact with each other so that their surfaces made surface-to-surface contact. The thermocompression bonding processes was then conducted under vacuum furnace (about 5.0×10⁻⁶ torr) to minimize the influence of oxidation. The bonding processes were performed for sixty minutes at bonding temperatures of 275 to 300° C. and a bonding pressure of 1 MPa.

The resulting test specimens were then mounted in an epoxy mount at room temperature without any external pressure. The specimens were polished before undergoing microscopy study in which the microstructures of the resulting bond interfaces 20 between the copper films 14 and pillars 16 were examined under an optical microscope and a scanning electron microscope (SEM) to analyze the bond interfaces 20. Microstructural analysis was performed with a bright-field transmission electron microscope (BFTEM).

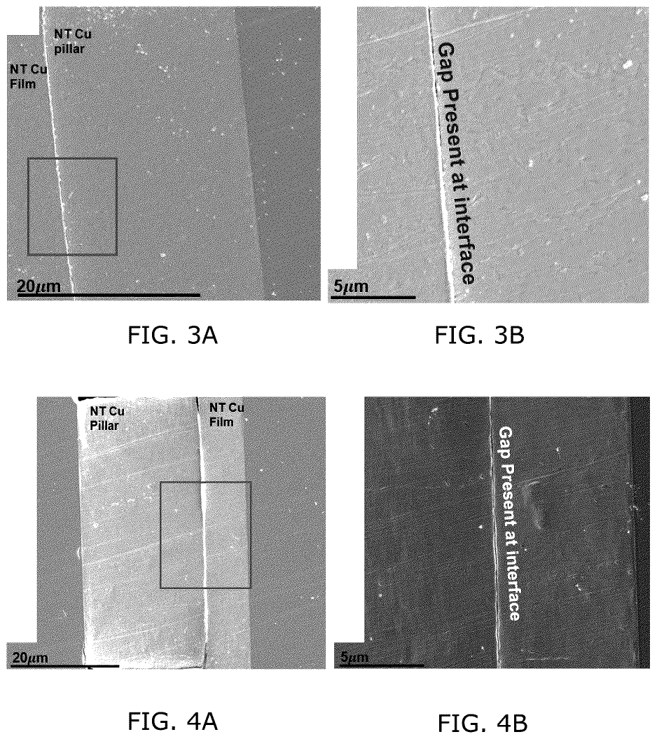

One specimen (FIGS. 3A and 3B) utilized a silver buffer layer having a thickness of 10 nm. Thermocompression bonding was performed at 275° C. After removal from the furnace the two Si 110 substates of the specimen remained attached to each other without separation. However, a gap is visible between the film and a pillar in FIGS. 3A and 3B, indicating that only partial bonding occurred.

Another specimen utilized a titanium buffer layer having a thickness of 10 nm. Thermocompression bonding was performed at a bonding temperature of 300° C., after which it was observed that the film and pillars were completely separate without any bonding.

A third specimen utilized a pure copper buffer layer deposited by sputtering to a thickness of 10 nm. Thermocompression bonding was performed at a bonding temperature of 300° C., after which it was observed that the film and pillars were only partially bonded with a gap present at the bond interface, as shown in FIGS. 4A and 4B.

On the basis of the first, second, and third specimens, it was concluded that buffer layers formed of silver, titanium, and copper were not capable of achieving a quality bond between a copper film and copper pillars at a relatively low bonding temperature (275° C. or 300° C.) and a relatively low bonding pressure (1 MPa).

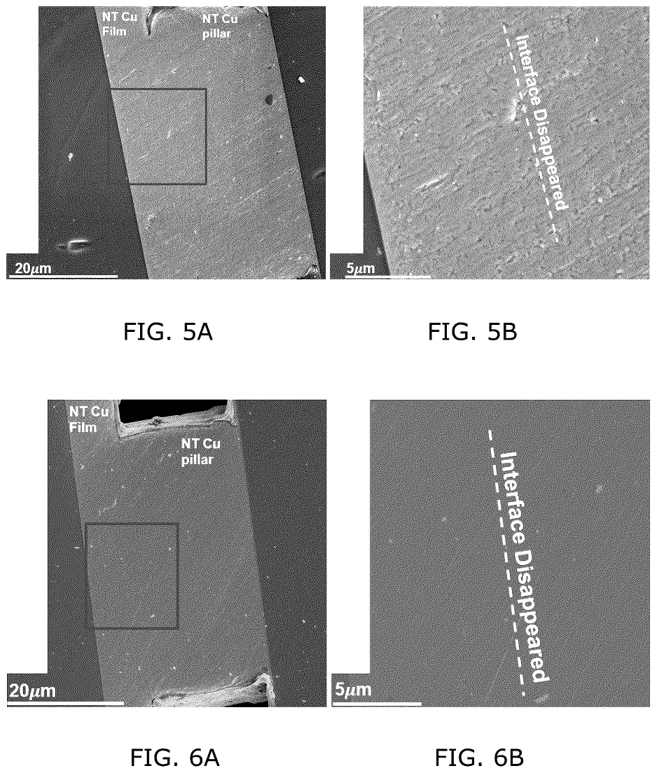

A fourth specimen utilized a cobalt buffer layer deposited to a thickness of 10 nm. Thermocompression bonding was performed at a bonding temperature of 300° C. Examination of the specimen showed smooth diffusion characteristics with pillars smoothly attached to the film without any observation of a clear bond interface, as shown in FIGS. 5A and 5B. Higher magnification images under SEM also indicated good bonding results. As such, it was concluded that a buffer layer formed of cobalt was capable of achieving a quality bond between a copper film and copper pillars at a relatively low bonding temperature (300° C.) and a relatively low bonding pressure (1 MPa).

A fifth specimen utilized a nickel buffer layer deposited to a thickness of 10 nm. Nickel is a unique element in relation to copper because of their isomorphous nature and complete solubility. Thermocompression bonding was conducted at a bonding temperature of 300° C., the results of which are shown in FIGS. 6A and 6B and from which it was concluded that a successful bond was achieved without the presence of any detectable bond interface, indicating that diffusion occurred at the bond interface at a relatively low bonding temperature (300° C.) and relatively low bonding pressure (1 MPa).

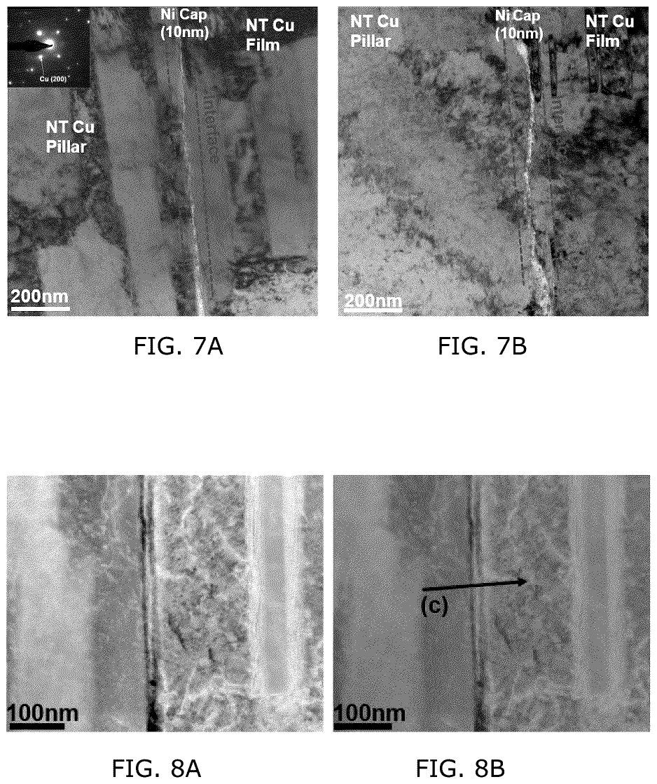

In order to further assess the bonding characteristics at a bond interface achieved with a nickel buffer layer, the fifth specimen of FIGS. 6A and 6B was further analyzed under a bright field transmission electron microscope (BFTEM). FIGS. 7A and 7B contain BFTEM images captured at bond interfaces of the fifth specimen and reveal the presence of a smooth nickel layer between the copper pillars and film of the specimen with very few voids observed at the bond interface. As discussed above, voids are one of the major inhibitors of achieving a smooth diffusion at a bond interface.

The surfaces of the films and pillars that mate to form the bond interfaces can be considered as crests and troughs. When the films and pillars first contact each other before bonding, the crests of their surfaces align with each other and come in contact with each other. Local plastic yielding is generated at the contacting crests due to higher stresses as compared to the troughs. Over time during thermocompression bonding, a stress gradient forms along these contact regions, which drives the diffusion process by increasing the area of the contact regions and decreasing the amplitude of their peaks.

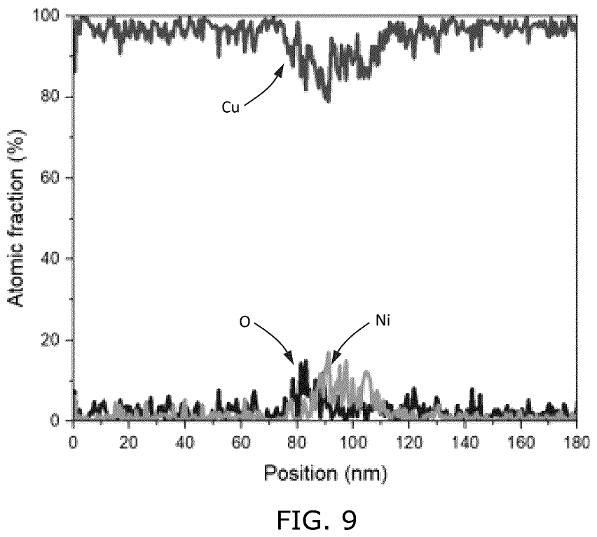

An energy dispersive X-ray spectroscopy (EDS) analysis was performed to obtain a clearer picture of the presence of Ni atoms within the bond interface of the nickel (fifth) specimen. The Ni concentration map showed the gradual interdiffusion of Ni atoms towards the NT Cu film and pillars. This may be attributed to the isomorphous nature between copper and nickel and their solid solubility with each other. FIG. 8A is a high angle annular dark-field (HAADF) image of a bond interface between a pillar and the film of the fifth specimen, and FIG. 8B is an HAADF image of the bond interface superimposed with a compositional analysis of the bond interface. FIG. 9 is a graph containing a line scan profile along a line indicated by an arow in FIG. 8B and labeled (c) showing an increase in nickel concentration near the bond interface and a gradual decrease in oxygen concentration. From FIGS. 8A and 8B it was concluded that diffusion and the solid solubility of copper and nickel were critical factors for the bonding mechanism and the results seen in FIGS. 6A, 6B, 7A, and 7B.

In view of the foregoing, the ability was demonstrated for buffer layers of certain materials to influence the thermocompression bonding mechanism, and more particularly to enable successful thermocompression bonding at relatively low temperatures and pressures. As such, the thermocompression bonding process disclosed herein is well suited for use with silicon wafers used in packaging of integrated circuits in the semiconductor industry. Whereas buffer layers of certain materials (titanium) exhibited an adverse effect (no bonding) and certain other materials (silver and copper) did not exhibit any benefit (e.g., partial bonding), buffer layers formed of cobalt and nickel were demonstrated to achieve smooth bonding with no visible remnants of a bond interface.

On the basis of the investigations, it is believed that nickel or cobalt buffer layers having thicknesses of at least 10 nanometers and up to 2 micrometers could be used to obtain suitable results, more preferably about 10 nanometers to about 100 nanometers. Though the investigations evaluated buffer layers applied to the films, it is foreseeable that the buffer layers could instead or in addition be applied to the pillars, such as through a combination of sputtering and lithograph. Though the dimensions of the copper films and pillars are not believed to be critical, on the basis of the investigations it is believed that copper pillars having diameters of about 50 micrometers or less, for example, as small as 500 nanometers, and having heights of 20 micrometers or less, for example, as small as 1 micrometer, could be used with suitable results. Though cobalt and nickel buffer layers were evaluated, it is foreseeable that cobalt or nickel alloys (i.e., alloys that are predominantly either cobalt or nickel) could be used as buffer layers with suitable results. Additionally, the results obtained through the investigations are believed to be equally applicable to thermocompression bonding of materials other than NT copper, including copper alloys (i.e., alloys that are predominantly copper).

The investigations further suggest that acceptable results can be obtained with thermocompression parameters that include bonding temperatures of about 50° C. and up to about 400° C. and bonding pressures of at least 0.1 MPa and up to 100 MPa, more preferably bonding temperatures of about 50° C. to about 300° C. and bonding pressures of about 0.5 MPa to about 1 MPa. However, it should be appreciated that higher bonding temperatures and pressures promote thermocompression bonding, and therefore could be used though at the risk of incurring previously-noted adverse effects on the performance and integrity of integrated circuit devices that are being joined. Though the experiments were performed in a vacuum, it is foreseeable that a standard or inert atmosphere be used instead.

As previously noted above, though the foregoing detailed description describes certain aspects of one or more particular embodiments of the invention, alternatives could be adopted by one skilled in the art. For example, dimensions for the films, pillars, and buffer layers and temperatures and pressures could be used that differ from those utilized in the investigations, and the buffer layers could be utilized to thermocompression bond substrates other than silicon wafers. As such, and again as was previously noted, it should be understood that the invention is not necessarily limited to any particular embodiment described herein or illustrated in the drawings.

1. A process of bonding first and second substrates together, the process comprising:
mating a copper film on the first substrate with copper pillars on the second substrate so that a surface of the copper film contacts surfaces of the copper pillars and so that a buffer layer is between the surface of the copper film and the surfaces of the copper pillars, the buffer layer being cobalt or nickel; and thermocompression bonding the copper film to the copper pillars at a bonding temperature while the first and second substrates are subjected to compression that presses the copper film and the copper pillars together at a bonding pressure.

2. The process of claim 1, further comprising applying the buffer layer to the copper film prior to mating the copper film on the first substrate with the copper pillars on the second substrate.

3. The process of claim 1, wherein the bonding temperature is about 50° C. up to about 400° C. and the bonding pressure is about 0.1 MPa up to about 100 MPa.

4. The process of claim 1, wherein the bonding temperature is about 50° C. up to about 300° C.

5. The process of claim 1, wherein the bonding pressure is about 0.5 MPa to about 1 MPa.

6. The process of claim 1, wherein the buffer layer has a thickness of at least 10 nanometers and up to 2 micrometers.

7. The process of claim 1, wherein the buffer layer has a thickness of about 10 nanometers to about 100 nanometers.

8. The process of claim 1, wherein the buffer layer is cobalt and has a thickness of about 10 nanometers.

9. The process of claim 1, wherein the buffer layer is nickel and has a thickness of about 10 nanometers.

10. The process of claim 1, wherein the copper pillars have diameters of about 500 nanometers to about 50 micrometers and have heights of 1 micrometer and to about 20 micrometers.

11. The process of claim 1, wherein the thermocompression bonding is performed in a vacuum.

12. The process of claim 1, wherein the thermocompression bonding is performed for sixty minutes at the bonding temperature of 275 to 300° C. and at the bonding pressure of 1 MPa.

13. The process of claim 1, wherein the first and second substrates are silicon wafers that comprise integrated circuits.
